(19) United States
(12) Patent Application Publication
(10) Pub. No.: US 2026/0212930 A1
(43) Pub. Date: Jul. 23, 2026

(54) FLASH AND METHOD FOR CONTROLLING PROGRAM VOLTAGE OF SAME

(71) Applicant: Shanghai Huahong Grace Semiconductor Manufacturing Corporation, Shanghai (CN)

(72) Inventor: Guangjun YANG, Shanghai (CN)

(21) Appl. No.: 19/140,428

(22) PCT Filed: Sep. 27, 2023
(86) PCT No.: PCT/CN2023/122159

§ 371 Date: Jun. 18, 2025

(30) Foreign Application Priority Data
May 31, 2023 (CN) 202310637353.1

(51) Int. Cl. G11C 16/10; G11C 16/04; G11C 16/34; H10B 41/30

(52) U.S. Cl. CPC G11C 16/10; G11C 16/0425; G11C 16/3427; G11C 16/3459; H10B 41/30

(57) ABSTRACT

The present application discloses a flash, wherein all memory cells of the same column are connected in parallel between two adjacent bit lines. A program operation on a selected memory bit is configured with the following three stages: a first program stage for realizing first-time program, wherein a bit line program voltage of a first bit line close to the selected memory bit is set to a first positive voltage; a second verify stage for performing verification; and a third program stage for realizing second-time program, wherein the bit line program voltage is set to a second positive voltage. The third program stage is performed when a verification result is abnormal, and the first positive voltage is less than the second positive voltage. The present application further discloses a method for controlling a program voltage of a flash.

### TECHNICAL FIELD

The present application relates to the field of semiconductor integrated circuits, and in particular to a flash. The present application also relates to a method for controlling a program voltage of a flash.

### BACKGROUND

FIG. 1 is a schematic diagram of a circuit structure of a memory cell 101 of an existing flash. FIG. 2 is a schematic diagram of a sectional structure of the memory cell 101 of the existing flash. FIG. 3 is a diagram of an array structure of the existing flash. The existing flash includes a plurality of memory cells 101, an array cell 301 consists of a plurality of memory cells 101, and a plurality of array cells 301 are arranged to form the array structure of the flash.

Each memory cell 101 is a split-gate floating-gate device.

Referring to FIG. 2, the split-gate floating-gate device includes: a first source-drain region 205a and a second source-drain region 205b that are symmetrical, a plurality of split first gate structures each having a floating gate 104 that are located between the first source-drain region 205a and the second source-drain region 205b, and a second gate structure 103 located between the first gate structures. Each of the first gate structures has a control gate 105 at the top of the floating gate 104.

The split-gate floating-gate device is a double split-gate floating-gate device, and there are two first gate structures, which are denoted with labels 102a and 102b, respectively.

The split-gate floating-gate device is an N-type device, and the first source-drain region 205a and the second source-drain region 205b each are composed of an N+ region.

A P-type doped channel region is located between the first source-drain region 205a and the second source-drain region 205b and covered by each first gate structure and the second gate structure 103. The first source-drain region 205a and the second source-drain region 205b are both formed on a P-type semiconductor substrate 201 and are self-aligned with outer side faces of two corresponding first gate structures. The channel region is composed of the P-type semiconductor substrate 201 between the first source-drain region 205a and the second source-drain region 205b or is formed by further doping the P-type semiconductor substrate 201.

The second source-drain region 205b of the memory cell 101 is connected to a second source-drain electrode, which is to be connected to a bit line BL1.

The first source-drain region 205a of the memory cell 101 is connected to a first source-drain electrode, which is to be connected to a bit line BL0.

Each first gate structure is formed by a stack of a tunneling dielectric layer 202, the floating gate 104, a control gate dielectric layer 203, and the control gate 105.

Each second gate structure 103 is formed by a stack of a word line gate dielectric layer 204 and a word line gate 106.

The control gate 105 is connected to a corresponding control gate line, and the word line gate 106 is connected to a word line (WL). In FIG. 1, the memory cell 101 includes two first gate structures, and therefore there are two control gate lines, which are denoted with CG0 and CG1 respectively. The control gate 105 of the first gate structure 102a is connected to the control gate line CG0, and the control gate 105 of the first gate structure 102b is connected to the control gate line CG1.

During program of a selected memory bit of the memory cell 101, taking a memory bit, i.e., memory bit ‘a’, corresponding to the floating gate 104 in the first gate structure 102a in FIG. 2 as the selected memory bit, voltages applied re as shown in Table I, including the following:

A 6 V voltage is applied to the control gate line CG1 to turn on a regional segment of a channel region controlled by the first gate structure 102b, i.e., making the channel region conductive.

A 1.5 V voltage is applied to the word line WL to open a regional segment of a channel region controlled by the second gate structure 103.

A program current Idp is applied to the bit line BL1.

A 9 V high voltage is applied to the control gate line CG0, and a 4.5 V high voltage is applied to the bit line BL0. As such, after the program current reaches the bottom of the first gate structure 102a by passing through regional segments of channel regions controlled by the first gate structure 102b and the second gate structure 103, since the control gate line CG0 and the bit line BL1 are both at high voltages, source hot-electron injection program can be achieved.

TABLE I

| BL0 | CG0 | WL | CG1 | BL1 |
|---|---|---|---|---|
| (V) | (V) | (V) | (V) | (V) |
| 4.5 | 9 | 1.5 | 6 | Idp |

Referring to FIG. 3, all the memory cells 101 in the array structure are arranged in rows and columns.

The first source-drain region 205a and the second source-drain region 205b of each memory cell 101 are connected to the corresponding bit lines, and each bit line is shared by two adjacent columns of the memory cells 101.

All the memory cells 101 of the same column are connected in parallel between two adjacent bit lines, and FIG. 3 shows four memory cells 101 adjacent to one another on the same column, which are labeled with labels 101a, 101b, 101c, and 101d respectively. It can be seen that the first source-drain region 205a of each memory cell 101 and the first source-drain region 205a of the adjacent memory cell 101 on the same column are connected together to the bit line BL0, and the second source-drain region 205b of each memory cell 101 and the second source-drain region 205b of the adjacent memory cell 101 on the same column are connected together to the bit line BL1.

Taking the memory cell 101a as the selected memory cell and a memory bit in the memory cell 101a close to the bit line BL0, i.e., memory bit ‘a’, as the selected memory bit, voltages applied during program of the selected memory bit ‘a’ are as described above, i.e., the voltages applied according to Table I.

However, as can be seen from FIG. 3, a 4.5 V bit line program voltage is required to be applied to the bit line BL0. However, the bit line BL0 is connected to not only the first source-drain region 205a of the selected memory cell 101a, but also to the first source-drain regions 205a of the other memory cells 101 on the same column. For example, in FIG. 3, the first source-drain regions 205a of the memory cells 101b, 101c, and 101d are all connected to the bit line BL0.

When the voltage of the bit line BL0 is relatively high, program disturb occurs to memory bits of all the memory cells 101 on the same column that are close to the bit line BL0. For example, memory bits ‘b’, ‘c’, and ‘d’ in FIG. 3 may all undergo the program disturb caused by the bit line BL0.

In order to reduce the program disturb caused by the bit line BL0, a reduction of the voltage of the bit line BL0 is required. However, the reduction of the voltage of the bit line BL0 may reduce the program efficiency, thus resulting in weak program of the selected memory bit ‘a’.

Therefore, in the existing program method, the voltage of the bit line BL0 is required to balance the program efficiency and the program disturb, while the requirements on the voltage of the bit line BL0 for improving the program efficiency and reducing the program disturb are exactly contradictory, thus making it difficult to set the voltage of the bit line BL0.

### BRIEF SUMMARY

According to some embodiments in this application, a flash provided by the present application includes a plurality of memory cells, wherein the plurality of memory cells are arranged to form an array structure of the flash, and all the memory cells in the array structure are arranged in rows and columns.

All the memory cells of the same column are connected in parallel between two adjacent bit lines.

For a selected memory cell, two bit lines connected to the selected memory cell are a first bit line and a second bit line respectively, and the first bit line is a bit line on a side close to a selected memory bit of the selected memory cell.

During a program operation on the selected memory bit of the selected memory cell, a bit line program voltage is applied to the first bit line, and the program operation is configured with the following three stages, which respectively are:
a first program stage for realizing first-time program of the selected memory bit,
wherein the bit line program voltage in the first program stage is set to a first positive voltage;
a second verify stage for verifying a state of the selected memory bit, wherein the bit line program voltage is set to 0 V; and
a third program stage for realizing second-time program of the selected memory bit, wherein the bit line program voltage in the second program stage is set to a second positive voltage.

In the second verify stage, if a verification result is normal, the third program stage is omitted; if the verification result is abnormal, the third program stage is performed.

The bit line program voltages required by all the memory cells in the array structure to achieve normal program are different.

The first positive voltage is less than the second positive voltage, the first positive voltage satisfies a requirement of programing a first part of the memory cells in the array structure, and program disturb is reduced by reducing the first positive voltage.

The first positive voltage cannot achieve normal program of a second part of the memory cells, the second positive voltage satisfies a requirement of programing the second part of the memory cells, a number of memory cells of the second part is less than a number of memory cells of the first part, and a cumulative effect of program disturb of the second positive voltage is alleviated by decreasing the number of memory cells of the second part.

In some cases, each memory cell is a split-gate floating-gate device.

The split-gate floating-gate device includes: a first source-drain region and a second source-drain region disposed symmetrically, a plurality of split first gate structures each having a floating gate that are located between the first source-drain region and the second source-drain region, and a second gate structure located between the first gate structures; each of the first gate structures has a control gate at the top of the floating gate.

The first source-drain region and the second source-drain region of each memory cell are connected to the corresponding bit lines.

The first source-drain region of each memory cell and the first source-drain region of the adjacent memory cell on the same column are connected together, and the second source-drain region of each memory cell and the second source-drain region of the adjacent memory cell on the same column are connected together.

In some cases, the split-gate floating-gate device is a double split-gate floating-gate device, and there are two first gate structures.

In some cases, the split-gate floating-gate device is an N-type device, and the first source-drain region and the second source-drain region each are composed of an N+ region.

A P-type doped channel region is located between the first source-drain region and the second source-drain region and covered by each first gate structure and the second gate structure, and each first gate structure and the second gate structure respectively control regional segments of the channel region covered thereby.

In some cases, in the array structure, the second gate structures of all the memory cells on the same row are all connected to a word line of the same row, and the control gates of the first gate structures of all the memory cells on the same row are all connected to a control gate line of the same row.

During the program operation on the selected memory bit of the selected memory cell, a word line program voltage is applied to the word line corresponding to the selected memory cell, and a control gate program voltage is applied to the control gate line corresponding to the selected memory bit of the selected memory cell.

During the program operation, the word line program voltage and the control gate program voltage are set as follows:

In the first program stage, the control gate program voltage is set to a third positive voltage, and the word line program voltage is set to a fourth positive voltage.

In the third program stage, the control gate program voltage is set to a fifth positive voltage, and the word line program voltage is set to a sixth positive voltage.

The third positive voltage is greater than the fifth positive voltage, and the fourth positive voltage is less than the sixth positive voltage, so as to improve the program efficiency in the first program stage.

In some cases, in the second verify stage, the control gate program voltage is set to 0 V, a seventh positive voltage serves as the word line program voltage, and the seventh positive voltage is greater than the sixth positive voltage.

In some cases, each first gate structure is formed by a stack of a tunneling dielectric layer, the floating gate, a control gate dielectric layer, and the control gate.

Each second gate structure is formed by a stack of a word line gate dielectric layer and a word line gate.

In some cases, the three stages of the program operation are controlled by means of a first program signal, the first program signal includes two pulses, a first pulse defines the first program stage, a second pulse defines the third program stage, and an interval region between the first pulse and the second pulse defines the second verify stage.

In some cases, a proportion of the memory cells of the first part is more than 90%.

In order to solve the above technical problem, in the method for controlling a program voltage of a flash provided by the present application, the flash includes a plurality of memory cells, the plurality of memory cells are arranged to form an array structure of the flash, and all the memory cells in the array structure are arranged in rows and columns.

All the memory cells of the same column are connected in parallel between two adjacent bit lines.

For a selected memory cell, two bit lines connected to the selected memory cell are a first bit line and a second bit line respectively, and the first bit line is a bit line on a side close to a selected memory bit of the selected memory cell.

During a program operation on the selected memory bit of the selected memory cell, a bit line program voltage is applied to the first bit line.

During the program operation, the method for controlling a program voltage includes the following steps:
configuring a first program stage to perform first-time program of the selected memory bit during the first program stage, wherein the bit line program voltage in the first program stage is set to a first positive voltage;
configuring a second verify stage to verify a state of the selected memory bit during the second verify stage, wherein the bit line program voltage is set to 0 V; and
configuring a third program stage to perform second-time program of the selected memory bit during the third program stage, wherein the bit line program voltage in the second program stage is set to a second positive voltage.

In the second verify stage, if a verification result is normal, the third program stage is omitted; if the verification result is abnormal, the third program stage is performed.

The bit line program voltages required by all the memory cells in the array structure to achieve normal program are different.

The first positive voltage is less than the second positive voltage, the first positive voltage satisfies a requirement of programing a first part of the memory cells in the array structure, and program disturb is reduced by reducing the first positive voltage.

The first positive voltage cannot achieve normal program of a second part of the memory cells, the second positive voltage satisfies a requirement of programing the second part of the memory cells, a number of memory cells of the second part is less than a number of memory cells of the first part, and a cumulative effect of program disturb of the second positive voltage is alleviated by decreasing the number of memory cells of the second part.

In some cases, each memory cell is a split-gate floating-gate device.

The split-gate floating-gate device includes: a first source-drain region and a second source-drain region disposed symmetrically, a plurality of split first gate structures each having a floating gate that are located between the first source-drain region and the second source-drain region, and a second gate structure located between the first gate structures; each of the first gate structures has a control gate at the top of the floating gate.

The first source-drain region and the second source-drain region of each memory cell are connected to the corresponding bit lines.

The first source-drain region of each memory cell and the first source-drain region of the adjacent memory cell on the same column are connected together, and the second source-drain region of each memory cell and the second source-drain region of the adjacent memory cell on the same column are connected together.

In some cases, the split-gate floating-gate device is a double split-gate floating-gate device, and there are two first gate structures.

In some cases, the split-gate floating-gate device is an N-type device, and the first source-drain region and the second source-drain region each are composed of an N+ region.

A P-type doped channel region is located between the first source-drain region and the second source-drain region and covered by each first gate structure and the second gate structure, and each first gate structure and the second gate structure respectively control regional segments of the channel region covered thereby.

In some cases, in the array structure, the second gate structures of all the memory cells on the same row are all connected to a word line of the same row, and the control gates of the first gate structures of all the memory cells on the same row are all connected to a control gate line of the same row.

During the program operation on the selected memory bit of the selected memory cell, a word line program voltage is applied to the word line corresponding to the selected memory cell, and a control gate program voltage is applied to the control gate line corresponding to the selected memory bit of the selected memory cell.

In the method for controlling a program voltage, the word line program voltage and the control gate program voltage are further set, including:
in the first program stage, setting the control gate program voltage to a third positive voltage, and setting the word line program voltage to a fourth positive voltage; and
in the third program stage, setting the control gate program voltage to a fifth positive voltage, and setting the word line program voltage to a sixth positive voltage.

The third positive voltage is greater than the fifth positive voltage, and the fourth positive voltage is less than the sixth positive voltage, so as to improve the program efficiency in the first program stage.

In some cases, in the second verify stage, the control gate program voltage is set to 0 V, a seventh positive voltage serves as the word line program voltage, and the seventh positive voltage is greater than the sixth positive voltage.

In some cases, each first gate structure is formed by a stack of a tunneling dielectric layer, the floating gate, a control gate dielectric layer, and the control gate.

Each second gate structure is formed by a stack of a word line gate dielectric layer and a word line gate.

In some cases, the three stages of the program operation are controlled by means of a first program signal, the first program signal includes two pulses, a first pulse defines the first program stage, a second pulse defines the third program stage, and an interval region between the first pulse and the second pulse defines the second verify stage.

In some cases, a proportion of the memory cells of the first part is more than 90%.

In a program operation setting of the existing flash, an excessively high bit line program voltage may cause program disturb, i.e., disturbing an unselected memory cell in the same column, while an excessively low bit line program voltage may reduce the program efficiency. In view of the above contradiction, the present application configures three stages in the program operation. In the first program stage, the bit line program voltage is set to the small first positive voltage, which can realize normal program of most, i.e., the first part, of the memory cells in the flash, and therefore the program disturb can be reduced by reducing the first positive voltage under the condition of maintaining the program efficiency. The second verify stage is used to verify a first-time program result of the first program stage, and if the verification result is normal, the subsequent third program stage is not required, that is, most of the memory cells do not require the third program stage. When the first-time program result is abnormal, the third program stage is carried out, and in the third program stage, the normal program of the remaining smaller part, i.e., the second part, of the memory cells, can be realized by increasing the second positive voltage, so that the program efficiency can be ensured by setting the second positive voltage. However, since the number of memory cells requiring the second-time program is smaller, the cumulative effect of the program disturb caused by the second positive voltage is alleviated, and finally the program disturb may also be reduced. Therefore, the present application may reduce or eliminate the program disturb under the condition of maintaining the program efficiency.

### BRIEF DESCRIPTION OF THE DRAWINGS

The present application will be further described in detail below with reference to the drawings and specific implementations:

FIG. 1 is a schematic diagram of a circuit structure of a memory cell of an existing flash;

FIG. 2 is a schematic diagram of a sectional structure of the memory cell of the existing flash;

FIG. 3 is a diagram of an array structure of the existing flash; and

FIG. 4 shows variation curves of bit line program voltages in three stages of a program operation on a flash of the embodiments of the present application.

### DETAILED DESCRIPTION OF THE DISCLOSURE

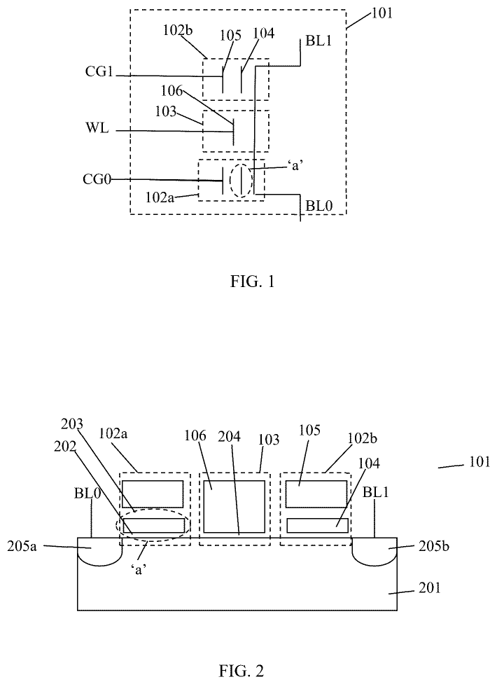

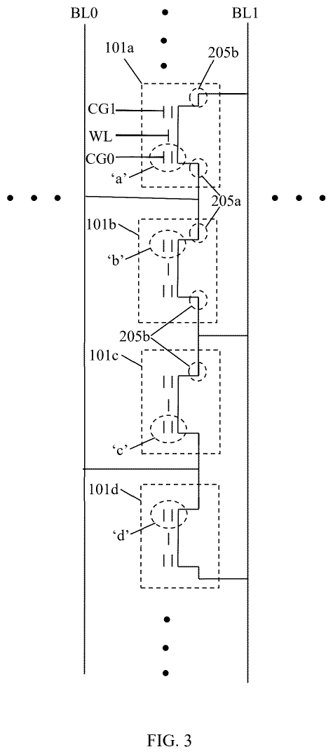

A structure of a memory cell 101 of a flash of embodiments of the present application is also as shown in FIGS. 1 and 2, and an array structure of the flash of the embodiments of the present application is also as shown in FIG. 3. The flash of the embodiments of the present application includes a plurality of memory cells 101.

In the embodiments of the present application, each memory cell 101 is a split-gate floating-gate device.

Referring to FIG. 2, the split-gate floating-gate device includes: a first source-drain region 205a and a second source-drain region 205b that are symmetrical, a plurality of split first gate structures each having a floating gate 104 that are located between the first source-drain region 205a and the second source-drain region 205b, and a second gate structure 103 located between the first gate structures. Each of the first gate structures has a control gate 105 at the top of the floating gate 104.

The split-gate floating-gate device is a double split-gate floating-gate device, and there are two first gate structures, which are denoted with labels 102a and 102b, respectively.

In some embodiment, the split-gate floating-gate device is an N-type device, and the first source-drain region 205a and the second source-drain region 205b each are composed of an N+ region.

A P-type doped channel region is located between the first source-drain region 205a and the second source-drain region 205b and covered by each first gate structure and the second gate structure 103. Each first gate structure and the second gate structure 103 respectively control regional segments of the channel region covered thereby. The first source-drain region 205a and the second source-drain region 205b are both formed on a P-type semiconductor substrate 201 and are self-aligned with outer side faces of two corresponding first gate structures. The channel region is composed of the P-type semiconductor substrate 201 between the first source-drain region 205a and the second source-drain region 205b or is formed by further doping the P-type semiconductor substrate 201.

The first source-drain region 205a of the memory cell 101 is connected to a first source-drain electrode, which is to be connected to a bit line BL0.

The second source-drain region 205b of the memory cell 101 is connected to a second source-drain electrode, which is to be connected to a bit line BL1.

Each first gate structure is formed by a stack of a tunneling dielectric layer 202, the floating gate 104, a control gate dielectric layer 203, and the control gate 105.

Each second gate structure 103 is formed by a stack of a word line gate dielectric layer 204 and a word line gate 106.

The control gate 105 is connected to a corresponding control gate line, and the word line gate 106 is connected to a word line (WL). In FIG. 1, the memory cell 101 includes two first gate structures, and therefore there are two control gate lines, which are denoted with CG0 and CG1 respectively. The control gate 105 of the first gate structure 102a is connected to the control gate line CG0, and the control gate 105 of the first gate structure 102b is connected to the control gate line CG1.

Referring to FIG. 3, the plurality of memory cells 101 are arranged to form an array structure of the flash, and all the memory cells 101 in the array structure are arranged in rows and columns. The first source-drain region 205a and the second source-drain region 205b of each memory cell 101 are connected to the corresponding bit lines, and each bit line is shared by two adjacent columns of the memory cells 101.

All the memory cells 101 of the same column are connected in parallel between two adjacent bit lines, and FIG. 3 shows four memory cells 101 adjacent to one another on the same column, which are labeled with labels 101a, 101b, 101c, and 101d respectively. It can be seen that the first source-drain region 205a of each memory cell 101 and the first source-drain region 205a of the adjacent memory cell 101 on the same column are connected together to the bit line BL0, and the second source-drain region 205b of each memory cell 101 and the second source-drain region 205b of the adjacent memory cell 101 on the same column are connected together to the bit line BL1.

In the array structure, the second gate structures 103 of all the memory cells 101 on the same row are all connected to a word line WL of the same row, and the control gates of the first gate structures of all the memory cells 101 on the same row are all connected to a control gate line of the same row. In FIG. 3, in a row structure of the memory cells 101 of the same row, there are two control gate lines, which are denoted with CG0 and CG1 respectively. The control gate 105 of the first gate structure 102a of each memory cell 101 on the same row is connected to the control gate line CG0, and the control gate 105 of the first gate structure 102b of each memory cell 101 on the same row is connected to the control gate line CG1.

For a selected memory cell 101, two bit lines connected to the selected memory cell 101 are a first bit line and a second bit line respectively, and the first bit line is a bit line on a side close to a selected memory bit of the selected memory cell 101. For example, when the selected memory cell 101 is a memory cell 101a in FIG. 3 and the selected memory bit is a memory bit ‘a’, the first bit line is the bit line BL0 and the second bit line is the bit line BL1. In the following description, illustration is performed with examples in which the memory cell 101a is used as the selected memory cell and the memory bit ‘a’ is used as the selected memory bit ‘a’, a control gate line corresponding to the selected memory bit ‘a’ is the control gate line corresponding to the label CG0.

During a program operation on the selected memory bit ‘a’ of the selected memory cell 101a, a bit line program voltage is applied to the first bit line BL0.

In the embodiments of the present application, during the program operation on the selected memory bit ‘a’ of the selected memory cell 101a, a word line program voltage is applied to the word line WL corresponding to the selected memory cell 101a, and a control gate program voltage is applied to the control gate line CG0 corresponding to the selected memory bit ‘a’ of the selected memory cell 101a.

The program operation is configured with the following three stages, which respectively are:
a first program stage for realizing first-time program of the selected memory bit ‘a’, wherein the bit line program voltage in the first program stage is set to a first positive voltage;
a second verify stage for verifying a state of the selected memory bit ‘a’, wherein the bit line program voltage is set to 0 V; and
a third program stage for realizing second-time program of the selected memory bit ‘a’, wherein the bit line program voltage in the second program stage is set to a second positive voltage.

In the second verify stage, if a verification result is normal, the third program stage is omitted; if the verification result is abnormal, the third program stage is performed.

The bit line program voltages required by all the memory cells 101 in the array structure to achieve normal program are different.

The first positive voltage is less than the second positive voltage, the first positive voltage satisfies a requirement of programing a first part of the memory cells 101 in the array structure, and program disturb is reduced by reducing the first positive voltage.

The first positive voltage cannot achieve normal program of a second part of the memory cells 101, the second positive voltage satisfies a requirement of programing the second part of the memory cells 101, a number of memory cells of the second part is less than a number of memory cells of the first part, and a cumulative effect of program disturb of the second positive voltage is alleviated by decreasing the number of memory cells of the second part.

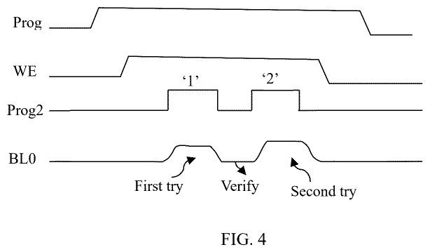

FIG. 4 shows variation curves of bit line program voltages in the three stages of the program operation on the flash of the embodiments of the present application. In the embodiments of the present application, the three stages of the program operation are controlled by means of a first program signal Prog2, and a curve of the first program signal Prog2 in FIG. 4 is also denoted by Prog2. It can be seen that the first program signal Prog2 includes two pulses, which are labeled with ‘1’ and ‘2’ respectively. A first pulse ‘1’ defines the first program stage, a second pulse ‘2’ defines the third program stage, and an interval region between the first pulse ‘1’ and the second pulse ‘2’ defines the second verify stage.

In FIG. 4, the bit line program voltage is a voltage of the first bit line BL0, so a curve of the bit line program voltage is also denoted by BL0. The bit line program voltage rises to the first positive voltage in a time period defined by the first pulse ‘1’, falls to 0 V in a time period defined by the interval region between the first pulse ‘1’ and the second pulse ‘2’, and rises to the second positive voltage in a time period defined by the second pulse ‘2’. Therefore, the three phases of the program operation can be controlled by means of the first program signal Prog2.

In some embodiments, a control signal includes the program signal Prog and a write enable signal We. During the program operation, the program signal Prog switches to a high level; the write enable signal We switches to an enable signal, and in FIG. 4, the write enable signal We is also enabled at a high level.

In some embodiments, a proportion of the memory cells 101 of the first part is more than 90%. For example, the proportion of the memory cells 101 of the first part is 95%, so that 95% of the memory cells 101 in the flash memory require only the first-time program and do not require the second-time program; while only 5% of the memory cells 101 require the second-time program. As such, the first-time program is weak disturb program, i.e., dispersed program, which can achieve program of most of the memory cells 101; the second-time program is strong disturb program, i.e., convergence program, which can ultimately achieve program of all the memory cells 101. Since a total number of times of the second-time program is reduced, the program disturb caused by the second-time program is also reduced, and finally the program disturb is also reduced. In FIG. 4, the first-time program is denoted by First try, the second verify stage is denoted by Verify, and the second-time program is denoted by Second try.

In the embodiments of the present application, during the program operation, the word line program voltage and the control gate program voltage are set as follows:

In the first program stage, the control gate program voltage is set to a third positive voltage, and the word line program voltage is set to a fourth positive voltage.

In the third program stage, the control gate program voltage is set to a fifth positive voltage, and the word line program voltage is set to a sixth positive voltage.

The third positive voltage is greater than the fifth positive voltage, and the fourth positive voltage is less than the sixth positive voltage, so as to improve the program efficiency in the first program stage.

In the second verify stage, the control gate program voltage is set to 0 V, a seventh positive voltage serves as the word line program voltage, and the seventh positive voltage is greater than the sixth positive voltage.

Variation curves of the word line program voltage and the control gate program voltage are not shown in FIG. 4. With reference to the curve BL0, it can be seen that the word line program voltage and the control gate program voltage also undergo a three-stage variation just like BL0, except that corresponding magnitudes are different.

In methods of some specific embodiments, the program operation of the embodiments of the present application can be realized using parameters in Table II below.

TABLE II

| | BL0 (V) | CG0 (V) | WL (V) |
|---|---|---|---|
| First try | 3.6 | 9.5 | 1.3 |
| Verify | 0 | 0 | 3 |
| Second try | 4 | 9.2 | 1.4 |

In Table II, BL0 denotes the bit line program voltage, CG0 denotes the control gate program voltage, and WL denotes the word line program voltage.

Upon comparison with Table I, it can be seen that in the embodiments of the present application, the voltage of BL0 is reduced during the First try, thus reducing the program disturb; CG0 is increased, and WL is reduced, thus improving the program efficiency, and thereby compensating for the reduction in the program efficiency caused by the reduction in BL0.

In the embodiments of the present application, a voltage is also required to be applied to the control gate line corresponding to an unselected memory bit, e.g., the control gate line corresponding to the label CG1 in FIG. 3, as well as a program current Idp to be applied to the second bit line, e.g., the bit line BL1. If the control gate line voltage of the unselected memory bit is applied to the First try and the Second try to make a regional segment of a channel region controlled by the first gate structure corresponding to the unselected memory bit conductive, the voltage of CG1 may also be 6 V as shown in Table I at this time.

In a program operation setting of the existing flash, an excessively high bit line program voltage may cause program disturb, i.e., disturbing an unselected memory cell in the same column, while an excessively low bit line program voltage may reduce the program efficiency. In view of the above contradiction, the embodiments of the present application configure three stages in the program operation. In the first program stage, the bit line program voltage is set to the small first positive voltage, which can realize normal program of most, i.e., the first part, of the memory cells in the flash, and therefore the program disturb can be reduced by reducing the first positive voltage under the condition of maintaining the program efficiency. The second verify stage is used to verify a first-time program result of the first program stage, and if the verification result is normal, the subsequent third program stage is not required, that is, most of the memory cells do not require the third program stage. When the first-time program result is abnormal, the third program stage is carried out, and in the third program stage, the normal program of the remaining smaller part, i.e., the second part, of the memory cells, can be realized by increasing the second positive voltage, so that the program efficiency can be ensured by setting the second positive voltage. However, since the number of memory cells requiring the second-time program is smaller, the cumulative effect of the program disturb caused by the second positive voltage is alleviated, and finally the program disturb may also be reduced. Therefore, the embodiments of the present application may reduce or eliminate the program disturb under the condition of maintaining the program efficiency.

The embodiments of the present application provide a method for controlling a program voltage of a flash.

In the method of the embodiments of the present application, a structure of a memory cell 101 of the flash is also as shown in FIGS. 1 and 2, and an array structure of the flash is also as shown in FIG. 3. The flash includes a plurality of memory cells 101.

In the method of the embodiments of the present application, each memory cell 101 is a split-gate floating-gate device.

Referring to FIG. 2, the split-gate floating-gate device includes: a first source-drain region 205a and a second source-drain region 205b that are symmetrical, a plurality of split first gate structures each having a floating gate 104 that are located between the first source-drain region 205a and the second source-drain region 205b, and a second gate structure 103 located between the first gate structures. Each of the first gate structures has a control gate 105 at the top of the floating gate 104.

The split-gate floating-gate device is a double split-gate floating-gate device, and there are two first gate structures, which are denoted with labels 102a and 102b, respectively.

In some embodiment, the split-gate floating-gate device is an N-type device, and the first source-drain region 205a and the second source-drain region 205b each are composed of an N+ region.

A P-type doped channel region is located between the first source-drain region 205a and the second source-drain region 205b and covered by each first gate structure and the second gate structure 103. Each first gate structure and the second gate structure 103 respectively control regional segments of the channel region covered thereby. The first source-drain region 205a and the second source-drain region 205b are both formed on a P-type semiconductor substrate 201 and are self-aligned with outer side faces of two corresponding first gate structures. The channel region is composed of the P-type semiconductor substrate 201 between the first source-drain region 205a and the second source-drain region 205b or is formed by further doping the P-type semiconductor substrate 201.

The first source-drain region 205a of the memory cell 101 is connected to a first source-drain electrode, which is to be connected to a bit line BL0.

The second source-drain region 205b of the memory cell 101 is connected to a second source-drain electrode, which is to be connected to a bit line BL1.

Each first gate structure is formed by a stack of a tunneling dielectric layer 202, the floating gate 104, a control gate dielectric layer 203, and the control gate 105.

Each second gate structure 103 is formed by a stack of a word line gate dielectric layer 204 and a word line gate 106.

The control gate 105 is connected to a corresponding control gate line, and the word line gate 106 is connected to a word line (WL). In FIG. 1, the memory cell 101 includes two first gate structures, and therefore there are two control gate lines, which are denoted with CG0 and CG1 respectively. The control gate 105 of the first gate structure 102a is connected to the control gate line CG0, and the control gate 105 of the first gate structure 102b is connected to the control gate line CG1.

Referring to FIG. 3, the plurality of memory cells 101 are arranged to form an array structure of the flash, and all the memory cells 101 in the array structure are arranged in rows and columns. The first source-drain region 205a and the second source-drain region 205b of each memory cell 101 are connected to the corresponding bit lines, and each bit line is shared by two adjacent columns of the memory cells 101.

All the memory cells 101 of the same column are connected in parallel between two adjacent bit lines, and FIG. 3 shows four memory cells 101 adjacent to one another on the same column, which are labeled with labels 101a, 101b, 101c, and 101d respectively. It can be seen that the first source-drain region 205a of each memory cell 101 and the first source-drain region 205a of the adjacent memory cell 101 on the same column are connected together to the bit line BL0, and the second source-drain region 205b of each memory cell 101 and the second source-drain region 205b of the adjacent memory cell 101 on the same column are connected together to the bit line BL1.

In the array structure, the second gate structures 103 of all the memory cells 101 on the same row are all connected to a word line WL of the same row, and the control gates of the first gate structures of all the memory cells 101 on the same row are all connected to a control gate line of the same row. In FIG. 3, in a row structure of the memory cells 101 of the same row, there are two control gate lines, which are denoted with CG0 and CG1 respectively. The control gate 105 of the first gate structure 102a of each memory cell 101 on the same row is connected to the control gate line CG0, and the control gate 105 of the first gate structure 102b of each memory cell 101 on the same row is connected to the control gate line CG1.

For a selected memory cell 101, two bit lines connected to the selected memory cell 101 are a first bit line and a second bit line respectively, and the first bit line is a bit line on a side close to a selected memory bit of the selected memory cell 101. For example, when the selected memory cell 101 is a memory cell 101a in FIG. 3 and the selected memory bit is a memory bit ‘a’, the first bit line is the bit line BL0 and the second bit line is the bit line BL1. In the following description, illustration is performed with examples in which the memory cell 101a is used as the selected memory cell and the memory bit ‘a’ is used as the selected memory bit ‘a’, a control gate line corresponding to the selected memory bit ‘a’ is the control gate line corresponding to the label CG0.

During a program operation on the selected memory bit ‘a’ of the selected memory cell 101a, a bit line program voltage is applied to the first bit line BL0.

In the method of the embodiments of the present application, during the program operation on the selected memory bit ‘a’ of the selected memory cell 101a, a word line program voltage is applied to the word line WL corresponding to the selected memory cell 101a, and a control gate program voltage is applied to the control gate line CG0 corresponding to the selected memory bit ‘a’ of the selected memory cell 101a.

During the program operation, the method for controlling a program voltage includes the following steps:
configuring a first program stage to perform first-time program of the selected memory bit ‘a’ during the first program stage, wherein the bit line program voltage in the first program stage is set to a first positive voltage;
configuring a second verify stage to verify a state of the selected memory bit ‘a’ during the second verify stage, wherein the bit line program voltage is set to 0 V; and
configuring a third program stage to perform second-time program of the selected memory bit ‘a’ during the third program stage, wherein the bit line program voltage in the second program stage is set to a second positive voltage.

In the second verify stage, if a verification result is normal, the third program stage is omitted; if the verification result is abnormal, the third program stage is performed.

The bit line program voltages required by all the memory cells 101 in the array structure to achieve normal program are different.

The first positive voltage is less than the second positive voltage, the first positive voltage satisfies a requirement of programing a first part of the memory cells 101 in the array structure, and program disturb is reduced by reducing the first positive voltage.

The first positive voltage cannot achieve normal program of a second part of the memory cells 101, the second positive voltage satisfies a requirement of programing the second part of the memory cells 101, a number of memory cells of the second part is less than a number of memory cells of the first part, and a cumulative effect of program disturb of the second positive voltage is alleviated by decreasing the number of memory cells of the second part.

FIG. 4 shows variation curves of bit line program voltages in the three stages of the program operation on the flash of the embodiments of the present application. In the method of the embodiments of the present application, the three stages of the program operation are controlled by means of a first program signal Prog2, and a curve of the first program signal Prog2 in FIG. 4 is also denoted by Prog2. It can be seen that the first program signal Prog2 includes two pulses, which are labeled with ‘1’ and ‘2’ respectively. A first pulse ‘1’ defines the first program stage, a second pulse ‘2’ defines the third program stage, and an interval region between the first pulse ‘1’ and the second pulse ‘2’ defines the second verify stage.

In FIG. 4, the bit line program voltage is a voltage of the first bit line BL0, so a curve of the bit line program voltage is also denoted by BL0. The bit line program voltage rises to the first positive voltage in a time period defined by the first pulse ‘1’, falls to 0 V in a time period defined by the interval region between the first pulse ‘1’ and the second pulse ‘2’, and rises to the second positive voltage in a time period defined by the second pulse ‘2’. Therefore, the three phases of the program operation can be controlled by means of the first program signal Prog2.

In some embodiments, a control signal includes the program signal Prog and a write enable signal We. During the program operation, the program signal Prog switches to a high level; the write enable signal We switches to an enable signal, and in FIG. 4, the write enable signal We is also enabled at a high level.

In some embodiments, a proportion of the memory cells 101 of the first part is more than 90%. For example, the proportion of the memory cells 101 of the first part is 95%, so that 95% of the memory cells 101 in the flash memory require only the first-time program and do not require the second-time program; while only 5% of the memory cells 101 require the second-time program. As such, the first-time program is weak disturb program, i.e., dispersed program, which can achieve program of most of the memory cells 101; the second-time program is strong disturb program, i.e., convergence program, which can ultimately achieve program of all the memory cells 101. Since a total number of times of the second-time program is reduced, the program disturb caused by the second-time program is also reduced, and finally the program disturb is also reduced. In FIG. 4, the first-time program is denoted by First try, the second verify stage is denoted by Verify, and the second-time program is denoted by Second try.

In the method of the embodiments of the present application, according to the method for controlling a program voltage, the word line program voltage and the control gate program voltage are further set, including:
in the first program stage, setting the control gate program voltage to a third positive voltage, and setting the word line program voltage to a fourth positive voltage; and
in the third program stage, setting the control gate program voltage to a fifth positive voltage, and setting the word line program voltage to a sixth positive voltage.

The third positive voltage is greater than the fifth positive voltage, and the fourth positive voltage is less than the sixth positive voltage, so as to improve the program efficiency in the first program stage.

In the second verify stage, the control gate program voltage is set to 0 V, a seventh positive voltage serves as the word line program voltage, and the seventh positive voltage is greater than the sixth positive voltage.

Variation curves of the word line program voltage and the control gate program voltage are not shown in FIG. 4. With reference to the curve BL0, it can be seen that the word line program voltage and the control gate program voltage also undergo a three-stage variation just like BL0, except that corresponding magnitudes are different.

In methods of some specific embodiments, the program operation of the embodiments of the present application can be realized using parameters in Table II below.

Upon comparison with Table I, it can be seen that in the method of the embodiments of the present application, the voltage of BL0 is reduced during the First try, thus reducing the program disturb; CG0 is increased, and WL is reduced, thus improving the program efficiency, and thereby compensating for the reduction in the program efficiency caused by the reduction in BL0.

In the method of the embodiments of the present application, a voltage is also required to be applied to the control gate line corresponding to an unselected memory bit, e.g., the control gate line corresponding to the label CG1 in FIG. 3, as well as a program current Idp to be applied to the second bit line, e.g., the bit line BL1. If the control gate line voltage of the unselected memory bit is applied to the First try and the Second try to make a regional segment of a channel region controlled by the first gate structure corresponding to the unselected memory bit conductive, the voltage of CG1 may also be 6 V as shown in Table I at this time.

The present application is described in detail above via specific embodiments, but these embodiments are not intended to limit the present application. Without departing from the principle of the present application, those skilled in the art can still make many variations and improvements, which should also be construed as falling into the protection scope of the present application.

1. A flash, comprising a plurality of memory cells, wherein the plurality of memory cells are arranged to form an array structure of the flash, and all the memory cells in the array structure are arranged in rows and columns;
all the memory cells of the same column are connected in parallel between two adjacent bit lines;
for a selected memory cell, two bit lines connected to the selected memory cell are a first bit line and a second bit line respectively, and the first bit line is a bit line on a side close to a selected memory bit of the selected memory cell;
during a program operation on the selected memory bit of the selected memory cell, a bit line program voltage is applied to the first bit line, and the program operation is configured with the following three stages, which respectively are:
a first program stage for realizing first-time program of the selected memory bit, wherein the bit line program voltage in the first program stage is set to a first positive voltage;
a second verify stage for verifying a state of the selected memory bit, wherein the bit line program voltage is set to 0 V; and
a third program stage for realizing second-time program of the selected memory bit, wherein the bit line program voltage in the second program stage is set to a second positive voltage;
in the second verify stage, if a verification result is normal, the third program stage is omitted; if the verification result is abnormal, the third program stage is performed;
the bit line program voltages required by all the memory cells in the array structure to achieve normal program are different;
the first positive voltage is less than the second positive voltage, the first positive voltage satisfies a requirement of programing a first part of the memory cells in the array structure, and program disturb is reduced by reducing the first positive voltage;
the first positive voltage cannot achieve normal program of a second part of the memory cells, the second positive voltage satisfies a requirement of programing the second part of the memory cells, a number of memory cells of the second part is less than a number of memory cells of the first part, and a cumulative effect of program disturb of the second positive voltage is alleviated by decreasing the number of memory cells of the second part.

2. The flash according to claim 1, wherein each memory cell is a split-gate floating-gate device;
the split-gate floating-gate device comprises: a first source-drain region and a second source-drain region disposed symmetrically, a plurality of split first gate structures each having a floating gate that are located between the first source-drain region and the second source-drain region, and a second gate structure located between the first gate structures; each of the first gate structures has a control gate at the top of the floating gate;
the first source-drain region and the second source-drain region of each memory cell are connected to the corresponding bit lines;
the first source-drain region of each memory cell and the first source-drain region of the adjacent memory cell on the same column are connected together, and the second source-drain region of each memory cell and the second source-drain region of the adjacent memory cell on the same column are connected together.

3. The flash according to claim 2, wherein the split-gate floating-gate device is a double split-gate floating-gate device, and there are two first gate structures.

4. The flash according to claim 3, wherein the split-gate floating-gate device is an N-type device, and the first source-drain region and the second source-drain region each are composed of an N+ region;
a P-type doped channel region is located between the first source-drain region and the second source-drain region and covered by each first gate structure and the second gate structure, and each first gate structure and the second gate structure respectively control regional segments of the channel region covered thereby.

5. The flash according to claim 2, wherein in the array structure, the second gate structures of all the memory cells on the same row are all connected to a word line of the same row, and the control gates of the first gate structures of all the memory cells on the same row are all connected to a control gate line of the same row;
during the program operation on the selected memory bit of the selected memory cell, a word line program voltage is applied to the word line corresponding to the selected memory cell, and a control gate program voltage is applied to the control gate line corresponding to the selected memory bit of the selected memory cell;
during the program operation, the word line program voltage and the control gate program voltage are set as follows:
in the first program stage, the control gate program voltage is set to a third positive voltage, and the word line program voltage is set to a fourth positive voltage;
in the third program stage, the control gate program voltage is set to a fifth positive voltage, and the word line program voltage is set to a sixth positive voltage;
the third positive voltage is greater than the fifth positive voltage, and the fourth positive voltage is less than the sixth positive voltage, so as to improve the program efficiency in the first program stage.

6. The flash according to claim 5, wherein in the second verify stage, the control gate program voltage is set to 0 V, a seventh positive voltage serves as the word line program voltage, and the seventh positive voltage is greater than the sixth positive voltage.

7. The flash according to claim 2, wherein the three stages of the program operation are controlled by means of a first program signal, the first program signal comprises two pulses, a first pulse defines the first program stage, a second pulse defines the third program stage, and an interval region between the first pulse and the second pulse defines the second verify stage.

8. The flash according to claim 1, wherein a proportion of the memory cells of the first part is more than 90%.

9. A method for controlling a program voltage of a flash, wherein the flash comprises a plurality of memory cells, the plurality of memory cells are arranged to form an array structure of the flash, and all the memory cells in the array structure are arranged in rows and columns;
all the memory cells of the same column are connected in parallel between two adjacent bit lines;
for a selected memory cell, two bit lines connected to the selected memory cell are a first bit line and a second bit line respectively, and the first bit line is a bit line on a side close to a selected memory bit of the selected memory cell;
during a program operation on the selected memory bit of the selected memory cell, a bit line program voltage is applied to the first bit line;
during the program operation, the method for controlling a program voltage comprises the following steps:
configuring a first program stage to perform first-time program of the selected memory bit during the first program stage, wherein the bit line program voltage in the first program stage is set to a first positive voltage;
configuring a second verify stage to verify a state of the selected memory bit during the second verify stage, wherein the bit line program voltage is set to 0 V; and
configuring a third program stage to perform second-time program of the selected memory bit during the third program stage, wherein the bit line program voltage in the second program stage is set to a second positive voltage;
in the second verify stage, if a verification result is normal, the third program stage is omitted; if the verification result is abnormal, the third program stage is performed;
the bit line program voltages required by all the memory cells in the array structure to achieve normal program are different;
the first positive voltage is less than the second positive voltage, the first positive voltage satisfies a requirement of programing a first part of the memory cells in the array structure, and program disturb is reduced by reducing the first positive voltage;
the first positive voltage cannot achieve normal program of a second part of the memory cells, the second positive voltage satisfies a requirement of programing the second part of the memory cells, a number of memory cells of the second part is less than a number of memory cells of the first part, and a cumulative effect of program disturb of the second positive voltage is alleviated by decreasing the number of memory cells of the second part.

10. The method for controlling a program voltage of a flash according to claim 9, wherein each memory cell is a split-gate floating-gate device;
the split-gate floating-gate device comprises: a first source-drain region and a second source-drain region disposed symmetrically, a plurality of split first gate structures each having a floating gate that are located between the first source-drain region and the second source-drain region, and a second gate structure located between the first gate structures; each of the first gate structures has a control gate at the top of the floating gate;
the first source-drain region and the second source-drain region of each memory cell are connected to the corresponding bit lines;
the first source-drain region of each memory cell and the first source-drain region of the adjacent memory cell on the same column are connected together, and the second source-drain region of each memory cell and the second source-drain region of the adjacent memory cell on the same column are connected together.

11. The method for controlling a program voltage of a flash according to claim 10, wherein the split-gate floating-gate device is a double split-gate floating-gate device, and there are two first gate structures.

12. The method for controlling a program voltage of a flash according to claim 11, wherein the split-gate floating-gate device is an N-type device, and the first source-drain region and the second source-drain region each are composed of an N+ region;
a P-type doped channel region is located between the first source-drain region and the second source-drain region and covered by each first gate structure and the second gate structure, and each first gate structure and the second gate structure respectively control regional segments of the channel region covered thereby.

13. The method for controlling a program voltage of a flash according to claim 10, wherein in the array structure, the second gate structures of all the memory cells on the same row are all connected to a word line of the same row, and the control gates of the first gate structures of all the memory cells on the same row are all connected to a control gate line of the same row;
during the program operation on the selected memory bit of the selected memory cell, a word line program voltage is applied to the word line corresponding to the selected memory cell, and a control gate program voltage is applied to the control gate line corresponding to the selected memory bit of the selected memory cell;
in the method for controlling a program voltage, the word line program voltage and the control gate program voltage are further set, comprising:
in the first program stage, setting the control gate program voltage to a third positive voltage, and setting the word line program voltage to a fourth positive voltage; and
in the third program stage, setting the control gate program voltage to a fifth positive voltage, and setting the word line program voltage to a sixth positive voltage;
the third positive voltage is greater than the fifth positive voltage, and the fourth positive voltage is less than the sixth positive voltage, so as to improve the program efficiency in the first program stage.

14. The method for controlling a program voltage of a flash according to claim 13, wherein in the second verify stage, the control gate program voltage is set to 0 V, a seventh positive voltage serves as the word line program voltage, and the seventh positive voltage is greater than the sixth positive voltage.

15. The method for controlling a program voltage of a flash according to claim 10, wherein the three stages of the program operation are controlled by means of a first program signal, the first program signal comprises two pulses, a first pulse defines the first program stage, a second pulse defines the third program stage, and an interval region between the first pulse and the second pulse defines the second verify stage.

16. The method for controlling a program voltage of a flash according to claim 9, wherein a proportion of the memory cells of the first part is more than 90%.
